(19) United States
(12) Patent Application Publication
(10) Pub. No.: US 2013/0196856 A1
(43) Pub. Date: Aug. 1, 2013

(54) IRON BASED SUPERCONDUCTING STRUCTURES AND METHODS FOR MAKING THE SAME

(71) Applicants: Qiang Li, Setauket, NY (US); Weidong Si, Middle Island, NY (US)

(72) Inventors: Qiang Li, Setauket, NY (US); Weidong Si, Middle Island, NY (US)

(73) Assignee: BROOKHAVENSCIENCE ASSOICATES, LLC, Upton, NY (US)

(21) Appl. No.: 13/814,003

(22) PCT Filed: Aug. 2, 2011
(86) PCT No.: PCT/US11/46312

§ 371 Date: Apr. 12, 2013

Related U.S. Application Data
(60) Provisional application No. 61/370,165, filed on Aug. 3, 2010.

(51) Int. Cl. H01L 39/12; H01L 39/24

(52) U.S. Cl. CPC H01L 39/125; H01L 39/2412
USPC 505/191; 505/150; 505/237; 505/236; 505/238; 505/230; 505/470; 505/474; 505/434; 427/62; 29/599; 174/125.1; 428/141

(57) ABSTRACT

In some embodiments of the invention, superconducting structures are described. In certain embodiments the superconducting structures described are thin films of iron-based superconductors on textured substrates; in some aspects a method for producing thin films of iron-based superconductors on textured substrates is disclosed. In some embodiments applications of thin films of iron-based superconductors on textured substrates are described. Also contemplated is the formation of a film of iron-based superconductor having a thickness and an in-plane lattice constant formed on a textured substrate having a thickness and an in-plane lattice constant similar to the in-plane lattice constant of the iron-based superconductor.

### STATEMENT OF GOVERNMENT LICENSE RIGHTS

This invention was made with Government support under contract number DE-AC 02-98CH10886, awarded by the U.S. Department of Energy. The Government has certain rights in the invention.

### BACKGROUND OF THE INVENTION

1. Field of Invention

The invention relates to the field of thin films of iron-based superconductors and, in particular, to thin films of these superconductors on textured substrates. The invention also relates to methods of fabricating thin films of iron-based superconductors on textured substrates.

2. Background of the Related Art

High field applications of superconductors have been dominated by Nb₃Sn, a material which allows magnetic fields up to 20 T to be achieved at 4.2 K. However, Nb₃Sn wires typically require a post-winding heat-treatment, which is a technically-challenging manufacturing step. Although high temperature superconducting oxides (HTS) offer excellent superconducting properties, their characteristically high anisotropies and brittle textures, in addition to the high manufacturing costs, have limited their applications. In 2008, a new family of iron-based superconductors was found, which are semi-metallic low anisotropy materials with transition temperatures, T_{c}'s, up to 55 K (Ren, et al. Europhys. Lett. 83, 17002 (2008); incorporated herein by reference in its entirety). The combination of extremely high upper critical fields H_{c2}(0) (˜100 T), moderate anisotropies of H_{c2}^{ab}/H_{c2}^{a}, and high irreversibility fields, Hᵢᵣᵣ, makes this class of superconductors appealing for high field applications.

These iron-based superconductors can further be divided into those that belong to iron pnictides ((LaFeAsO, SrFe₂As₂, BaFe₂As₂, etc.) and those that belong to iron chalcogenides (FeTe, FeSe, etc.). Both have very attractive properties. A more detailed discussion of iron-based superconductors is provided in Balatsky et al. (Physics 2, 59 2009) and Xia et al. (Phys. Rev. Lett. 103, 037002, 2009). Each of the aforementioned publications is incorporated by reference in its entirety as if fully set forth in this specification.

However, chalcogenides hold several practical advantages over the pnictides. Although the T_{c}'s of chalcogenides are typically below 20 K, they exhibit lower anisotropies ˜2 with H_{c2}(0)' s approaching 50 T. The exceptionally high upper critical magnetic fields of chalcogenides are important for high-field applications such as MRI magnets and accelerator magnets. They also have the simplest structure among the iron-based superconductors and contain only two or three elements, which greatly simplifies their handling, unlike pnictides that contain toxic arsenic.

A lot of effort has gone into making high quality thin films of such materials. However, these films were made on crystalline substrates, which cannot be used to make superconducting tapes or wires for large scale applications. For practical applications, superconductors of this class must be made on substrates, which provide support and can be made in long tapes or wires. However, due to the lattice mismatch between these substrates and those materials, it is very difficult to grow such films.

There is therefore a continuing need to develop manufacturing methods that would allow the formation of iron-based superconductors such as iron chalcogenides and iron pnictides into films, wires or tapes that can be used for industrial and research use, e.g., to wind superconducting magnets.

### SUMMARY

Recognizing the challenges of obtaining high-quality thin films of iron-based superconductors on substrates, the technology described herein offers a way of fabricating thin films of iron chalcogenide- and iron pnictides-based superconductors on textured substrates and discloses structures that result from employing the technology.

Thus, in some embodiments, growth of iron-based superconductors on textured substrates is described. In some embodiments, the iron-based superconductors are iron chalcogenide-based superconductors, while in other embodiments, the iron-based superconductors are iron pnictides-based superconductors. The textured substrates preferably have similar in-plane lattice constants as the superconductors, although it is especially preferred if the textured substrates are nearly lattice-matched to the in-plane lattice constants of the superconductors.

In some embodiments, the iron-based superconductors are iron chalcogenides that comprise Fe_{z}SeₓTe₁₋ₓ, where 0≦x≦1 and 0.7≦z≦1.3. In some embodiments, the superconducting material comprises FeS_{y}SeₓTe_{1-x-y}, where 0≦x+y≦1. In some cases, the iron chalcogenide superconductor is doped with various dopants, including oxygen.

In some embodiments, the iron-based superconductor is an iron pnictide, either an oxypnictide or a non-oxypnictide. The iron-oxypnictide can be expressed as M—Fe_{y}AsO₁₋ₓFₓ, where 0≦x≦1, 0.4≦y≦1.6 and M is one or more of rare-earth metals selected from Sc, Y, La, Ce, Pr, Nd, Pm, Sm, Eu, Gd, Tb, Dy, Ho, Er, Tm, Yb, or Lu, one or more of alkali metals selected from Li, Na, K, Rb, or Cs, or one or more alkali-earth metals selected from Be, Mg, Ca, Sr, or Ba although La is preferred. The stoichiometric composition of M is preferably 1, e.g., La _{0.5}Y_{0.5}. The iron-nonoxypnictide can be expressed as M—Fe_{y}AsₓF_{z}, where 1≦x≦2, 0.6≦y≦2.0 and 0≦z≦1. As with iron-oxypnictides, M for iron-nonoxypnictides is selected from one or more rare-earth metals, one or more alkali metals, or one or more alkali-earth metals. In some cases, the iron pnictide superconductor may be doped with various dopants, preferably fluorine.

In some embodiments, substrates comprise layers of buffer materials that improve the texture of the base to render it more suitable for formation of iron-based superconductor films thereupon. In some cases, a single layer of buffer material is used; in other cases, multiple layers of buffer materials are used.

In some embodiments, use of magnesium oxide (MgO) as a buffer layer is described. In other embodiments, cerium oxide (CeO₂) is used to texture the surface of a substrate. In yet other embodiments, textured substrates comprise layers of yttrium oxide (Y₂O₃) and/or yttria-stabilized zirconia (YSZ).

In some embodiments, methods for fabricating thin films of iron-based superconductors on buffered metal substrates are presented. In some embodiments substrates comprise oxides, polymers, including metallized and conducting polymers, and/or semiconductors.

In some embodiments, the superconducting thin films retain their inherent superconducting properties, including critical electrical currents, critical magnetic fields, and critical superconducting transition temperatures, and these properties are on par with those of films of similar composition and thickness to films grown on single-crystal substrates. In some cases, the superconducting properties of the thin films are better than those of bulk materials having the same composition.

In some embodiments, thin films of iron-based superconductors such as iron chalcogenide-based superconductors, on textured metal substrates are described.

In some embodiments, the superconducting structures described may be used in magnetic, electronic, and superconducting devices.

It should be understood that the foregoing, being a summary, is necessarily a brief description of some aspects of the invention, which may be better understood with reference to the drawings and the following detailed description.

### BRIEF DESCRIPTION OF THE DRAWINGS

As is common practice in the art, the following figures may not be drawn to scale. Schematic depictions are used to emphasize the particular features of the invention and as a reference for their description.

FIG. 1 shows a cross-sectional TEM (XTEM) image of an iron chalcogenide-based superconducting structure.

FIG. 2 shows a high-resolution XTEM (HR-XTEM) image of an iron chalcogenide-based superconducting structure.

FIG. 3 is a graph that illustrates the behavior of resistance with temperature and magnetic field in a thin film of FeSe_{0.5}Te_{0.5} on a MgO-buffered nickel alloy substrate prepared by ion beam-assisted deposition (IBAD).

FIG. 4 is a graph that depicts the behavior of resistance with temperature and magnetic field in a thin film of FeSe_{0.5}Te_{0.5} on a CeO₂-buffered nickel alloy substrate prepared by the rolling-assisted biaxially textured substrate (RABiTS) technique.

FIG. 5 is a graph that shows the behavior of critical current density of a FeSe_{0.5}Te_{0.5} thin film grown on single crystal substrate LaAlO₃ (LAO) with temperature and magnetic field.

FIG. 6 is a graph that shows the behavior of critical current density of a FeSe_{0.5}Te_{0.5} thin film grown on a RABiTS substrate with temperature and magnetic field.

FIG. 7 is an XRD θ-2θscan for a FeSe_{0.5}Te_{0.5} thin film grown on single crystal substrate SrTiO₃ (STO).

FIG. 8 is a graph that shows a cross-sectional TEM (XTEM) image of an oxygen doped iron chalcogenide-based superconducting structure (Fe_{1.08}Te:Oₓ) on the STO substrate.

FIG. 9 is an XRD θ-2θscan for oxygen doped iron chalcogenide.

FIG. 10 is a graph that shows the resistance as a function of temperature in a thin film of Fe_{1.08}Te:Oₓ on a STO substrate.

FIG. 11a is a plot that shows J_{c}'s of FeSe_{0.5}Te_{0.5} films on LAO substrate at various temperatures with magnetic field parallel (solid symbols) and perpendicular (open symbols) to the ab plane (tape surface).

FIG. 11b is a plot that shows J_{c}'s of FeSe_{0.5}Te_{0.5} films on IBAD coated conductor at various temperatures with magnetic field parallel (solid symbols) and perpendicular (open symbols) to the ab plane (tape surface).

FIG. 12a is a plot that shows J_{c} at about 4.2 K of FeSe_{0.5}Te_{0.5} films compared with the data of 2G YBCO wire, TCP Nb47Ti and Nb₃Sn. For YBCO and FeSe_{0.5}Te_{0.5} the field direction is parallel to the c-axis.

FIG. 12b is a plot that shows volume pinning force Fₚ at about 4.2 K of FeSe_{0.5}Te_{0.5} films compared with the data of 2G YBCO wire, TCP Nb47Ti and Nb₃Sn. For YBCO and FeSe_{0.5}Te_{0.5} the field direction is parallel to the c-axis. Solid lines are Kramer's scaling approximations.

### DETAILED DESCRIPTION

The method described herein offers a way of fabricating thin films of iron-based superconductors, such as iron chalcogenides and pnictides, on textured substrates, although iron chalcogenides are preferred because they do not contain a toxic arsenic component. Preferably, the intrinsic electronic and magnetic properties of the superconducting structure generated by the disclosed method(s) are at least on par with those of a thin film of iron-based superconductor with the same composition and thickness formed on a bulk single crystal substrate.

Generally, the method encompasses preparing a textured substrate having an in-plane lattice constant, i.e., the distance between unit cells in a crystal lattice, similar to, or preferably closely lattice-matched with, the in-plane lattice constant of the superconductor, and forming a film of iron-based superconductor on the textured substrate, preferably by pulsed laser deposition. As provided in the specification, the term “similar” may be interpreted as having a mismatch of no more than ±10%, while a mismatch of less than ±5% is considered to be closely matched and is more preferred. Alternatively, it is preferred to have closely matched lattice constant value defined as being within ±0.2Å, although it is more preferable to have the lattice constant values within ±0.1Å.

In a preferred embodiment, the textured substrate is prepared by depositing a buffer layer on a base of the substrate in order to provide a template for growth of high-quality thin films of iron-based superconductors on the surface of the base layer.

Throughout this specification, the superconducting structures and processes for their manufacture are described with reference to one or more most preferred embodiments. However, it is to be understood that those skilled in the art may develop other combinatorial, structural, and functional modifications to the disclosed techniques of fabricating thin films of iron-based superconductors, e.g., iron chalcogenides, on textured substrates without significantly departing from the spirit and scope of the disclosed invention.

### I. Substrate Selection and Preparation

To maintain the superconducting properties of the iron-based superconducting material, the substrates should be chosen to have an in-plane lattice constant similar, or alternatively closely lattice-matched, to the in-plane lattice constant of the superconductor and preferably shaped into a ribbon, a tape or a wire. In a preferred embodiment, the substrate includes a base and a buffer, although the substrates only having a base textured to be similar to or to more closely match the in-plane lattice constant of the superconductor material are also envisioned. If the substrate has the base and the buffer, any compound can be used as the base material since the surface texture is created by the buffer. Examples of appropriate substrates include oxides, semiconductors, metallized and conducting polymers, and metals whose surfaces have been textured using buffer materials to have a similar or closely matched in-plane lattice constant of the superconductor material. The substrates may also be flexible and polycrystalline in nature. In a preferred embodiment, nickel and Ni alloys, such as Hastelloy® superalloys (Haynes Inter. Inc., Indiana), may be selected for their formability.

For use in electronic devices that use a planar configuration, silicon, silicon dioxide, silicon nitride, and glass may be useful when their surface is textured by deposition of an appropriate buffer material.

### II. Buffer Material Selection and Formation

The buffer layer is selected to provide a template for growth of high-quality thin films of iron-based superconductors. These materials should have a lattice constant close to that of iron-based superconductors. Examples of suitable compounds that may function as a buffer layer to provide a template for growth of iron-based superconductors include, but are not limited to, oxides, such as magnesium oxide (MgO), yttria-stabilized zirconia (YSZ), ceria (CeO₂), yttria (Y₂O₃), and a combination thereof. Preferably, the buffer layer has a thickness between 1 nm and 10 μm.

The buffer layer may be deposited on the substrate by any suitable method known in the art to produce layers having the desired properties. Preferably, the buffer layer may be deposited on the substrate by either a rolling-assisted biaxially textured substrate (RABiTS) technique or an ion beam-assisted deposition (IBAD) technique. The buffer material may be deposited in a single layer on which the iron-based superconductor is grown. In alternative, it may be deposited in a multilayer of the same or different buffer material to maintain high quality growth of the final layer, on which the iron-based superconductor is grown. In certain embodiments, several different layers of buffer materials may be necessary in order to maintain the best lattice match on substrates such as a metal or metal alloy. For example, in rolling-assisted biaxially textured substrate (RABiTS) or ion beam-assisted deposition (IBAD), yttria stabilized zirconia (YSZ) and ceria (CeO₂) may be used in series to form a much better buffer layer between the underlying metal of the substrates and the superconducting thin films, because CeO₂ is more closely lattice-matched with the superconductor and it is easier to form a textured structure of YSZ on metal or alloy substrates.

The buffer layer must also be grown in texture (biaxially aligned) on the selected substrates. For example, CeO₂ is fairly closely lattice-matched to FeSe_{0.5}Te_{0.5}, one of the iron-based superconductors having a relatively high superconducting transition temperature (T_{c}) and very large upper critical magnetic fields (H_{c2}). In a preferred embodiment, it can be grown in texture on Ni or Ni alloy using RABiTS or IBAD.

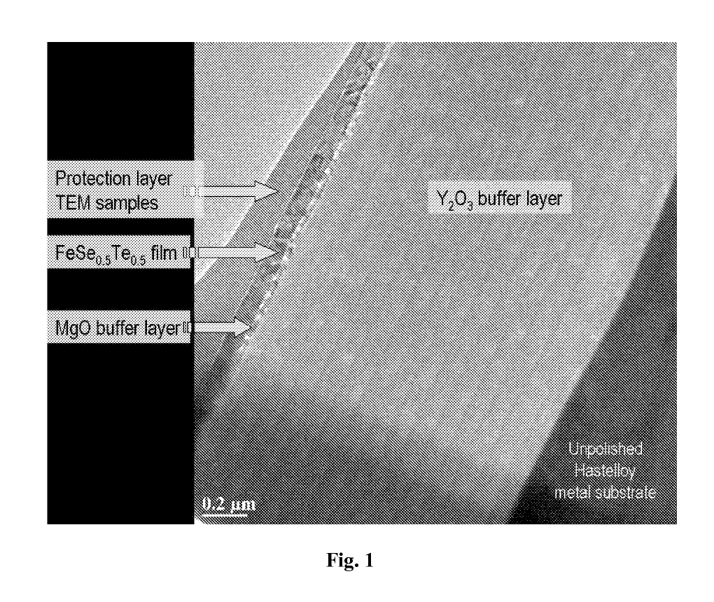

In an exemplary embodiment with reference to FIG. 1, the buffer layer is deposited by ion beam-assisted deposition (IBAD). In this exemplary embodiment, the IBAD technique starts with a polycrystalline nickel-based alloy, e.g. Hastelloy® tape and generates a highly in-plane-oriented template through deposition of YSZ or magnesium oxide (MgO) in the presence of a well-collimated “assisting” ion beam directed at an appropriate angle to the substrate. After epitaxial deposition of a thin cap layer (often CeO₂ in the case of YSZ or Y₂O₃), the template can be used for the deposition of superconductors.

### III. Superconductor Selection and Thin-Film Formation

The iron-based superconductors generated on the textured substrate by the disclosed method can be selected from iron chalcogenides or iron pnictides.

The iron chalcogenide based superconductors generated on the textured substrate by the disclosed method have a general formula Fe_{z}SeₓTe₁₋ₓ, where 0≦x≦1 and 0.7≦z≦1.3. In other embodiments, the iron chalcogenide based superconductors generated on the textured substrate by the disclosed method have a general formula FeS_{y}SeₓTe_{1-x-y}, where 0≦x+y≦1. Examples of such superconductors include, but are not limited to, FeTe, FeSe, FeSe_{0.5}Te_{0.5}, although, FeSe_{0.5}Te_{0.5}.is being preferred. The iron chalcogenide superconductor may also be doped with various dopants, although oxygen (e.g., FeTe:Oₓ) is preferred. For example, oxygen doping may be accomplished under oxygen pressure, during growth, of between 10⁻² to 10⁻⁷ Torr, more preferably between 10⁻³ to 10⁻⁶ Torr, and most preferably under pressure of about 10⁻⁴ Torr.

The iron pnictides based superconductors generated on the textured substrate by the disclosed method may be selected from oxypnictide or non-oxypnictide. The iron-oxypnictide can be expressed as M—Fe_{y}AsO₁₋ₓFₓ, where 0≦x≦1, 0.4≦y≦1.6 and M is one or more of rare-earth metals selected from Sc, Y, La, Ce, Pr, Nd, Pm, Sm, Eu, Gd, Tb, Dy, Ho, Er, Tm, Yb, or Lu, one or more of alkali metals selected from Li, Na, K, Rb, or Cs, or one or more alkali-earth metals selected from Be, Mg, Ca, Sr, or Ba, although, La is being preferred. The stoichiometric composition of M is preferably 1, e.g., La_{0.5}Y_{0.5}. The iron-nonoxypnictide can be expressed as M—Fe_{y}AsₓF_{z}, where 1≦x≦2, 0.6≦y≦2.0 and 0≦z≦1. As with iron-oxypnictides, M for iron-nonoxypnictides is selected from one or more rare-earth metals, one or more alkali metals, or one or more alkali-earth metals. Examples of iron pnictides include LaOFeAs, LiFeAs, and BaFe₂As₂. Similar to iron chalcogenide, the iron pnictide superconductor may also be doped with various dopants, although fluorine is preferred.

In the exemplary embodiment, the iron chalcogenide based superconductor may be fabricated on the surface of the textured substrate by any suitable method known in the art to produce layers having the desired properties. In a preferred embodiment, the iron chalcogenide based superconductor is deposited by pulsed laser deposition (PLD). In an exemplary embodiment, the iron chalcogenide based superconductor, e.g., FeSe_{0.5}Te_{0.5}, may be fabricated by placing the substrate into a deposition chamber; evacuating the deposition chamber to a pressure of about 10⁻⁶ Torr; heating the substrates to between 350° C. and 450° C.; hitting a target of a desired iron chalcogenide composition with a laser beam for a selected time period, where the laser beam has an energy density of about 3 J/cm² and a repetition rate of about 5 Hz; and turning off the substrate heater. The target of the desired iron chalcogenide may be prepared by inductive melting of Fe, Se, Te of desired stoichiometry at 650-750° C. Alternatively, without departing from the scope and spirit of the disclosed invention, the iron chalcogenide can be substituted with iron pnictide in the above described method.

### EXAMPLES

### Example 1

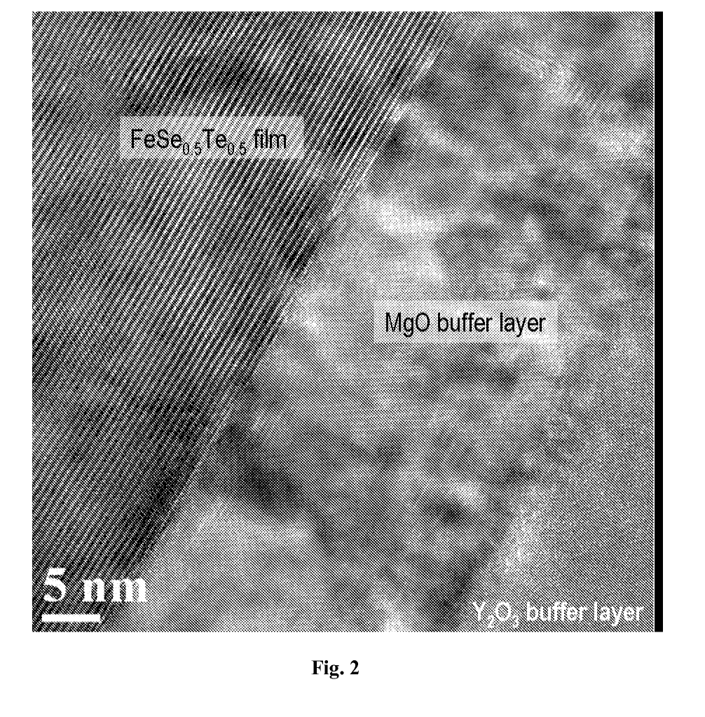

The films depicted in FIGS. 1 and 2 have a composition of FeSe_{0.5}Te_{0.5} and were grown by pulsed laser deposition (PLD). The films were deposited on single crystalline LaAlO₃ (LAO) substrates and buffered metal templates using a KrF excimer laser (wavelength: 248 nm) with an energy density of ˜3.0 J/cm² and a repetition rate of 5 Hz. The substrate temperature was varied from 350° C. to 450° C. The time to deposit the 400-nm film was about 30 minutes. Deposition and subsequent cooling were carried out under a vacuum of ˜10⁻⁶ torr. The heater was shut off after deposition to allow the structure to cool rapidly.

The templates were manufactured in two steps. First, an Y₂O₃ layer was made on unpolished Hastelloy® by sequential solution deposition to reduce the roughness of the tape surface, then a bi-axially textured MgO layer was deposited on top by the IBAD technique. (Matias, et al. J. Mater. Res. 24, 125 (2009); incorporated herein by reference in its entirety.) The very high tensile strength of Hastelloy® C-276 (0.8 GPa) allows the composite conductor to withstand the very high Lorentz force stresses produced by the 20-30 T magnetic fields.

FIG. 1 shows a cross-sectional TEM (XTEM) image of a 100 nm FeSe_{0.5}Te_{0.5} film on a buffered Hastelloy® (Hastelloy C-276 tapes) metal substrate that has a 1.3 gm thick Y₂O₃ planarization layer and a bi-axially textured IBAD MgO layer (including a 25 nm homo-epitaxial MgO). Interfaces appear smooth and abrupt, as does the surface of the FeSe_{0.5}Te_{0.5}.

FIG. 2 shows a high-resolution XTEM (HR-XTEM) image of the iron chalcogenide-based superconducting structure of FIG. 1. The interface between the MgO and the FeSe_{0.5}Te_{0.5} is abrupt and nearly epitaxial. The FeSe_{0.5}Te_{0.5} film was grown on the MgO layer with the c-axis perpendicular to the substrate. X-ray diffraction experiments have also confirmed the textured growth of FeSe_{0.5}Te_{0.5}, with in-plane and out-of-plane textures about 4.5° and 3.5° in full width half maximum, respectively. However, the IBAD film has a lower zero resistance T_{c}⁰ (˜11 K) compared to the bulk (−14 K), although the onset transition starts at approximately the same temperature. The film on LAO has a T_{c}⁰ ˜15 K, about 1 K above that of the bulk. Without being bound by theory, this may be because that MgO has a larger lattice mismatch with FeSe_{0.5}Te_{0.5} than LAO, which leads to more structural defects.

### Example 2

Resistivity was measured by the standard four-probe method in a physical property measurement system (Quantum Design, PPMS) and magnetization was measured in a superconducting quantum interference device (Quantum Design, MPMS).

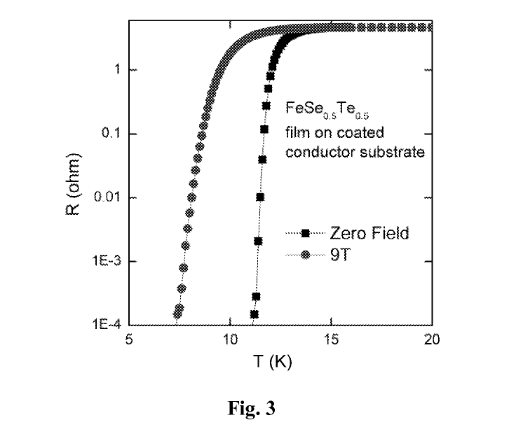

FIG. 3 depicts the behavior of resistance with temperature and magnetic field in a thin film of FeSe_{0.5}Te_{0.5} on a MgO-buffered nickel alloy substrate prepared by IBAD. The superconducting transition temperature is on par with that of bulk samples.

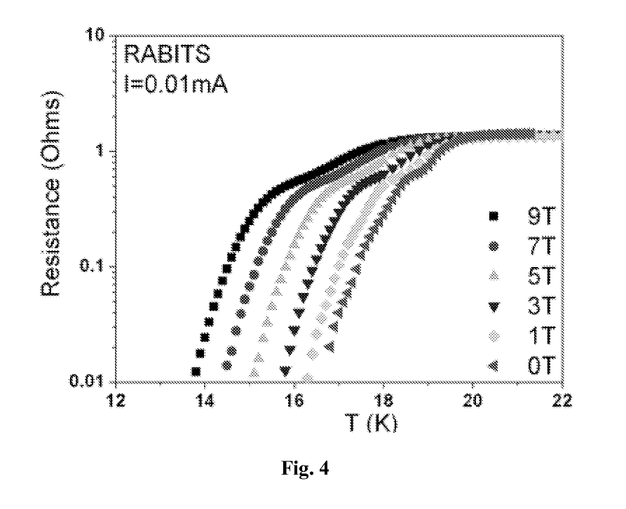

FIG. 4 depicts the behavior of resistance with temperature and magnetic field in a thin film of FeSe_{0.5}Te_{0.5} on a CeO₂-buffered nickel alloy substrate prepared by the RABiTS technique. The onset superconducting transition temperature is about the same as, if not higher than, that of similar films made on single crystal substrates.

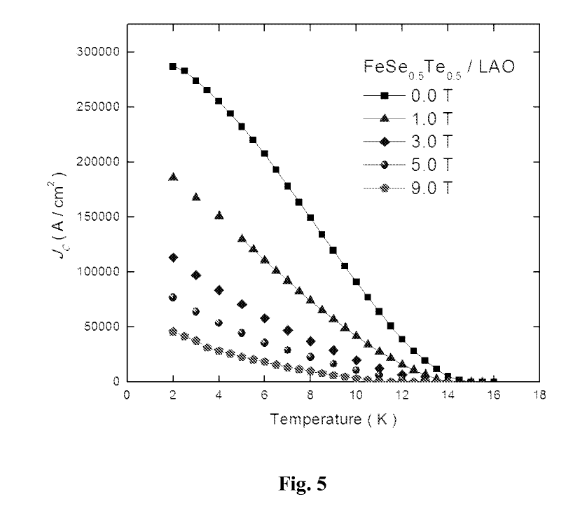

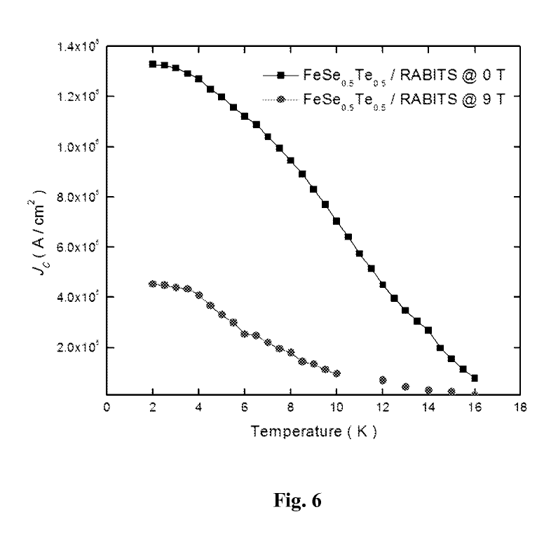

FIG. 5 shows the behavior of critical current density with temperature and magnetic field of a thin film of FeSe_{0.5}Te_{0.5} grown on a single-crystal substrate of LaAlO₃ (LAO) for comparison. FIG. 6 shows the behavior of critical current density of an FeSe_{0.5}Te_{0.5} thin film grown on a RABiTS substrate with temperature and magnetic field. J_{c} is much higher than that of the film grown on LAO. At 4.2K, and even in 9T of magnetic field, J_{c} is still as high as 0.4MA/cm². These results demonstrate that FeSe_{0.5}Te_{0.5} thin films grown on coated conductors are good for practical applications.

### Example 3

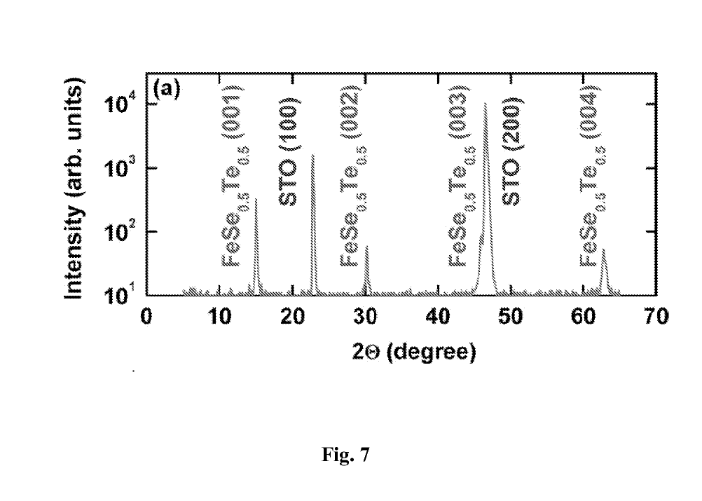

The conformation of the crystal lattice of the FeSe_{0.5}Te_{0.5} superconductors grown by PLD on the STO substrate was studied using X-ray diffraction spectroscopy. FIG. 7 illustrates the intensity spectrum from an XRD θ-2θ scan. Based on the XRD data, the in-plane lattice constant (a) of the superconductor was measured to be approximately 3.806Å, whereas the in-plane lattice constant of the STO substrate was measured to be approximately 3.905Å. The in-plane lattice constant of the fabricated superconductors was about the same with the bulk value, whereas the out-of-plane lattice constant (c) was always shorter.

### Example 4

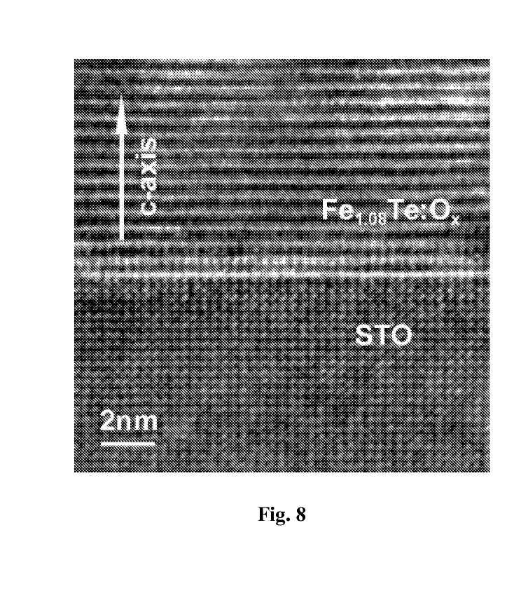

The iron chalcogenide FeTe superconductor was prepared with and without oxygen doping (Fe_{1.08}Te:Oₓ). FIG. 8 shows a cross-sectional TEM (XTEM) image of an iron chalcogenide-based superconducting structure doped with oxygen on the STO substrate. No complete superconducting transition was observed in FeTe films grown in vacuum down to 1.8 K. In contrast, oxygen doped FeTe films showed superconductivity.

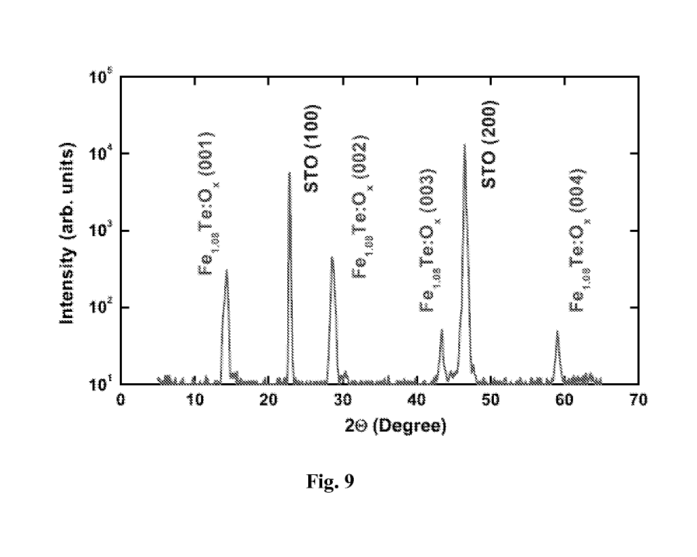

FIG. 9 illustrates the intensity spectrum from an XRD θ-2θ scan for an oxygen-doped iron chalcogenide. Based on the XRD data, the in-plane lattice constant (a) of the superconductor was measured to be approximately 3.821Å and out-of-plane constant (c) was about 6.275Å . These values are similar to bulk values.

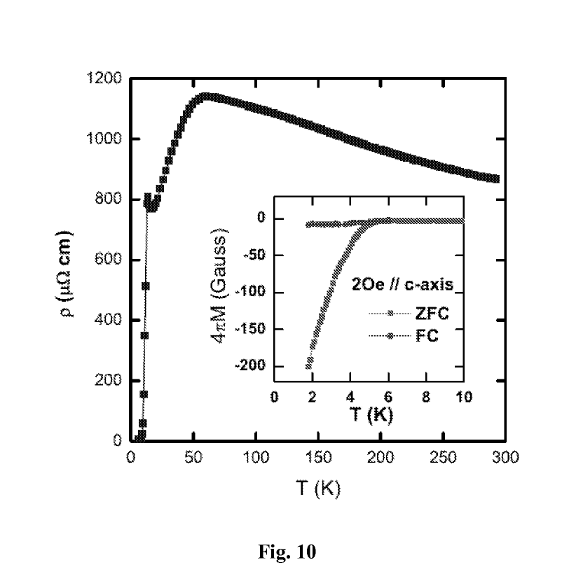

FIG. 10 depicts the behavior of resistance with temperature in a thin film of Fe_{1.08}Te:Oₓ on a STO substrate. The onset and zero resistance (T_{c}) were observed about 12 K and 8 K, respectively. FIG. 10 further shows that the metal-insulator transition is at around 60 K, which is lower than the metal-insulator transition observed in the bulk compound.

### Example 5

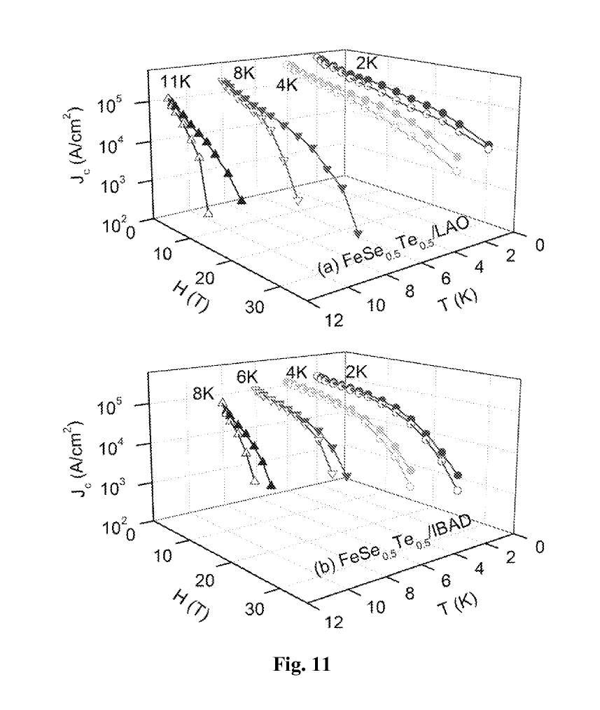

FIG. 11 shows the magnetic field dependence of J_{c} of films on both LAO and IBAD substrates at various temperatures. The J_{c} of films on LAO at T≦4 K is ˜5×10⁵ A/cm² in self-field and remains above 1×10⁴ A/cm² up to 35 T, the maximum field we could apply. Notably, the decrease of J_{c} does not accelerate much at high fields at liquid helium temperature, which is important for high field applications. The J_{c} decreases rather rapidly with field at T>8 K. Although the J_{c}'s of films on IBAD are lower than those of films on LAO at the same temperature and field, similar field behavior was observed. At T≦4 K, the self-field J_{c} is still as high as 2×10⁵ A/cm². In comparison, the higher decreasing rates of J_{c}'s in the films on IBAD were observed above 20 T, but J_{c}'s still remain higher than ˜b 1×10⁴ A/cm² at 25 T. Remarkably, in both films, J_{c}'s are nearly isotropic with little dependence on field direction at T≦4 K.

### Example 6

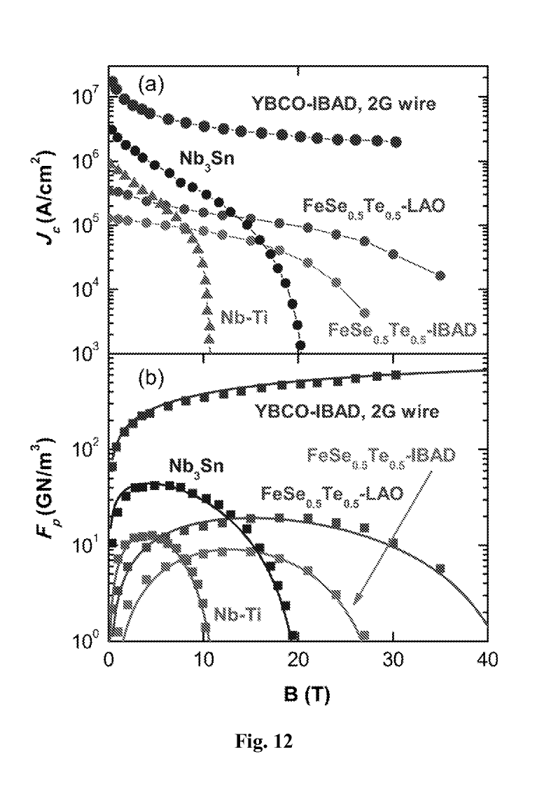

In FIGS. 12(a) and 12(b) the field dependence of J_{c}'s and volume pinning forces, Fₚ=μ₀H×J_{c}(B), were compared for FeSe_{0.5}Te_{0.5} films on LAO and IBAD substrates with the data for 2G YBCO wire, thermo-mechanically processed Nb₄₇Ti alloy, and small-grain Nb₃Sn wire at about 4.2 K. FeSe_{0.5}Te_{0.5} films exhibit superior high field performance (above 20 T) over those of low temperature superconductors. HTS's currently present a great challenge for long-length wire production due to the rapid decrease of J_{c} upon grain boundary misorientation, causing a subsequent increase in production costs. That may not be as severe in FeSe_{0.5}Te_{0.5}. The IBAD substrates have many low angle grain boundaries in the textured MgO template. However, the IBAD FeSe_{0.5}Te_{0.5} films are rather robust with the self-field J_{c} just a little lower than those of films on LAO.

It was reported that the grain boundary in a Ba(Fe₁ ₓCoₓ)₂As₂ system could reduce the J_{c} significantly. Without being bound by theory, the results seem to suggest that the grain boundaries in iron chalcogenides may behave differently, since they do not have a charge reservoir layer as in cuprates or Ba(Fe₁ ₓCoₓ)₂As₂, where carrier depletion occurs. Measurements of FeSe_{0.5}Te_{0.5} films grown on bi-crystalline substrates are most desirable to provide direct information on the misorientation angle dependence of J_{c}.

It is also possible that the relatively lower J_{c}'s in IBAD films is simply due to the lower T_{c}'s compared to those of the films on LAO, a result of the larger lattice mismatch between Mg0 and FeSe_{0.5}Te_{0.5}. An additional buffer layer of CeO₂, which has a better lattice match with FeSe_{0.5}Te_{0.5}, may improve the T_{c}, and hence raise the J_{c}. Alternatively, the elaborate oxide buffer structure, partially designed to protect the metal template from oxidation for 2G HTS wires, may not be needed since FeSe_{0.5}Te_{0.5} is made in vacuum. Growing a FeSe_{0.5}Te_{0.5} coating directly on textured metal tapes may be possible, potentially simplifying the synthesis procedure with a reduction of production costs. Wire applications require much thicker (over several lm) films, which may be grown by using a more scalable deposition technique, such as a low-cost web-coating process for 2G HTS wire.

In FIG. 12(b) it has been shown that the Kramer's scaling law approximation (solid line) ƒₚ˜h^{p}(1−h)^{q} for different types of superconductors at about 4.2 K, where ƒₚ=Fₚ/Fₚ^{max} is the normalized pinning force density and h=H/Hᵢᵣᵣ (Hᵢᵣᵣ is defined as the onset of zero resistance) is the reduced field. It was found that q˜2 for all types of superconductors, which is expected considering that the (1−h)² term describes the reduction of the superconducting order parameter at high field. The low field term p˜0.5 (h^{0.5}) was found for Nb₃Sn and YBCO and is associated with the saturation regime, where Fₚ^{max} changes little with the pinning center density because flux motion occurs by shearing of the vortex lattice, rather than by de-pinning The addition of BaZrO₃ nano-rods, which are very effective pinning centers at 77 K, resulted in a very minor pinning increase at 4.2 K. In contrast, the result of p˜1 found in the FeSe_{0.5}Te_{0.5} system is similar to the one in Nb—Ti. This is a strong evidence of point defect core pinning, most likely from the inhomogeneous distribution of Se and Te. In the core pinning regime Fₚ is a product of the individual Fₚ times, the pinning center density. This means that the J, of FeSe_{0.5}Te_{0.5} can still be enhanced by adding more defects to act as pinning centers. Due to the short coherence length, more pinning enhancement in FeSe_{0.5}Te_{0.5} is expected before reaching the coupling limit.

While the foregoing description has been made with reference to individual embodiments of the invention, it should be understood that those skilled in the art, making use of the teaching herein, may propose various changes and modifications without departing from the invention in its broader aspects.

The foregoing description being illustrative, the invention is limited only by the claims appended hereto.

1. A superconducting structure comprising
a film of iron-based superconductor having a thickness and an in-plane lattice constant; and
a textured substrate having a thickness and an in-plane lattice constant similar to the in-plane lattice constant of the iron-based superconductor,
wherein the superconductor film is formed on the textured substrate.

2. The superconducting structure of claim 1, wherein the in-plane lattice constant of the textured substrate has a mismatch of no more than 10% of the in-plane lattice constant of the iron-based superconductor.

3. The superconducting structure of claim 2, wherein the in-plane lattice constant of the textured substrate has a mismatch of no more than 5% of the in-plane lattice constant of the iron-based superconductor.

4. The superconducting structure of claim 1, wherein the iron-based superconductor comprises an iron chalcogenide.

5. The superconducting structure of claim 4, wherein the iron chalcogenide comprises compounds with a chemical formula
Fe_{z}SeₓTe₁₋ₓ,
wherein 0≦x≦1 and 0.7≦z≦1.3.

6. The superconducting structure of claim 5, wherein:
the superconductor is FeSe_{0.5}Te_{0.5}.

7. The superconducting structure of claim 1, wherein the iron-based superconductor comprises an iron pnictide.

8. The superconducting structure of claim 7, wherein the iron-pnictide is an iron-oxypnictide having a chemical formula
M—Fe_{y}AsO₁₋ₓFₓ,
wherein 0≦x≦1, 0.4≦y≦1.6 and M is one or more metals selected from the group consisting of Sc, Y, La, Ce, Pr, Nd, Pm, Sm, Eu, Gd, Tb, Dy, Ho, Er, Tm, Yb, Lu, Li, Na, K, Rb, Cs, Be, Mg, Ca, Sr, and Ba.

9. The superconducting structure of claim 8, wherein the rare-earth metal is La.

10. The superconducting structure of claim 9, wherein the iron-oxypnictide is LaOFeAs.

11. The superconducting structure of claim 7, wherein the iron-pnictide is an iron-non-oxypnictide having a chemical formula
M—Fe_{y}AsₓF_{z},
wherein 1≦x≦2, 0.6≦y≦2.0, 0≦z≦1 and M is one or more metals selected from the group consisting of Sc, Y, La, Ce, Pr, Nd, Pm, Sm, Eu, Gd, Tb, Dy, Ho, Er, Tm, Yb, Lu, Li, Na, K, Rb, Cs, Be, Mg, Ca, Sr, and Ba.

12. The superconducting structure of claim 11, wherein the iron-pnictide is LiFeAs or BaFe₂As₂.

13. The superconducting structure of claim 1, wherein the textured substrate comprises a base and a buffer layer.

14. The superconducting structure of claim 1, wherein the textured substrate comprises a base.

15. The superconducting structure of claim 13, wherein the buffer layer comprises an oxide.

16. The superconducting structure of claim 15, wherein the buffer layer comprises at least one material chosen from the group consisting of MgO, CeO₂, Y₂O₃, and YSZ.

17. The superconducting structure of claim 13, wherein the base comprises at least one material chosen from the group consisting of a metal, metal alloy, a semiconductor, an oxide, and a polymer.

18. The superconducting structure of claim 17, wherein the base comprises nickel.

19. The superconducting structure of claim 16, wherein the base comprises a nickel alloy.

20. The superconducting structure of claim 1, wherein the textured substrate is in the form of a ribbon, a tape, or a wire.

21. The superconducting structure of claim 13, wherein the base is in the form of a ribbon, a tape, or a wire.

22. The superconducting structure of claim 1, wherein the textured substrate is polycrystalline.

23. The superconducting structure of claim 13, wherein the base is polycrystalline.

24. The superconducting structure of claim 1, wherein the intrinsic electronic and magnetic properties of the superconductor are at least on par with those of a thin film of iron-based superconductor having the same composition and thickness formed on a bulk single crystal substrate.

25. The superconducting structure of claim 13, wherein the buffer layer has a thickness between 1 nm and 10 μm.

26. The superconducting structure of claim 1, wherein the thickness of the superconductor is between 10 nm and 10 μm.

27. A method of manufacturing a superconducting structure, the method comprising
forming a film of iron-based superconductor having a thickness and an in-plane lattice constant on a substrate having an in-plane lattice constant similar to the in-plane lattice constant of the superconductor.

28. The method of claim 27, further comprising depositing a buffer layer on a base to form the substrate.

29. The method of claim 28, wherein the buffer layer is grown under conditions that produce a texture on the base of the substrate.

30. The method of claim 29, wherein forming the superconductor film comprises depositing the superconductor by pulsed laser deposition.

31. The method of claim 30, wherein the pulsed laser deposition comprises the steps of
placing the substrate into a deposition chamber;
evacuating the deposition chamber to a pressure of about 10⁻⁶ Torr;
heating the substrates to between 350° C. and 450° C.;
hitting a target of a desired iron chalcogenide composition with a laser beam for a selected time period, the laser beam having an energy density of about 3 J/cm² and a repetition rate of about 5 Hz; and
turning off the substrate heater.

32. The method of claim 31, wherein the deposition chamber is evacuated to a pressure of between 10⁻² to 10⁻⁷ Torr oxygen pressure thereby producing an oxygen-doped superconductor film.

33. The method of claim 32, wherein the deposition chamber is evacuated to a pressure of between 10⁻³ to 10⁻⁶ Torr oxygen pressure thereby producing an oxygen-doped superconductor film.

34. The method of claim 33, wherein the deposition chamber is evacuated to a pressure of about 10⁻⁴ Torr oxygen pressure thereby producing an oxygen-doped superconductor film.

35. A method of using a superconducting structure, the method comprising:
forming a superconducting device from the superconducting structure, the superconducting structure comprising a textured substrate and a film of iron-based superconducting material formed on the substrate.

36. The method of claim 35, wherein forming the superconducting device comprises winding the superconducting structure into a magnet.

37. The method of claim 35, wherein forming the superconducting device comprises forming the superconducting structure into a ribbon or wire operable to conduct a supercurrent.

38. The method of claim 35, wherein forming the superconducting device comprises forming the superconducting structure into a current limiting device.

39. The method of claim 35, wherein forming the superconducting device comprises forming the superconducting structure into a radio frequency device.

40. The method of claim 35, further comprising detecting a response of the superconducting device to a stimulus applied thereto.
